(19) United States
(12) Patent Application Publication
(10) Pub. No.: US 2026/0314161 A1
(43) Pub. Date: Oct. 8, 2026

(54) DISPLAY PANEL AND MANUFACTURING METHOD THEREFOR, AND DISPLAY APPARATUS

(71) Applicants: Beijing BOE Technology Development Co., Ltd., Beijing (CN); BOE Technology Group Co., Ltd., Beijing (CN)

(72) Inventors: Zhuo CHEN, Beijing (CN); Qing DAI, Beijing (CN)

(21) Appl. No.: 19/477,819

(22) PCT Filed: Sep. 21, 2023
(86) PCT No.: PCT/CN2023/120520

§ 371 Date: Oct. 23, 2025

(51) Int. Cl. H10K 50/115; H10K 59/12; H10K 59/80

(52) U.S. Cl. CPC H10K 50/115; H10K 59/1201; H10K 59/873

(57) ABSTRACT

Provided in the present disclosure are a display panel and a manufacturing method therefor, and a display apparatus. The display panel comprises: a base substrate, wherein the base substrate has a display region and a peripheral region surrounding the display region, the peripheral region having a target region, which comprises at least one of an electrode joint region, part of the electrode joint region, a bonding region, part of the bonding region, an encapsulation region, part of the encapsulation region, and the whole peripheral region; residual photoresist, which is located on the base substrate and is located in the target region of the peripheral region; and a common layer, which is located on the base substrate and covers at least the display region of the base substrate, wherein the orthographic projection of the common layer on the base substrate does not overlap the orthographic projection of the residual photoresist on the base substrate, the common layer being used for transporting holes or electrons.

### TECHNICAL FIELD

The present disclosure relates to the field of display technology, particularly to a display panel and a manufacturing method therefor, and a display apparatus.

### BACKGROUND

With the continuous development and evolution of nanoscience and nanotechnology, the preparation of nanomaterials with specific patterned structures has gradually become an increasingly important research direction in the field of modern nanoscience and nanotechnology research. As a new type of nanomaterial, quantum dots have attracted keen attention from researchers due to numerous advantages since their emergence. The successful preparation of quantum dot light-emitting layers with specific patterns has not only expanded their application scope but also sparked another wave of research enthusiasm in the nanotechnology community. The quantum dots light-emitting diode display (QLED) is a new type of display technology developed based on an organic light-emitting display. The key difference between the two lies in that the light-emitting layer in the QLED is a quantum dot light-emitting layer. Its principle is that electrons/holes are injected into the quantum dot light-emitting layer through the electron/hole transport layers, and then electrons and holes recombine in the quantum dot light-emitting layer to emit light. Compared to the organic light-emitting diode display, the QLED offers advantages such as narrow emission peaks, high color saturation, and a wide color gamut.

### SUMMARY

The embodiments of the present disclosure provide a display panel and a manufacturing method therefor, and a display apparatus. The specific solutions are as follows.

The embodiments of the present disclosure provide a display panel, including: a base substrate, having a display region and a peripheral region surrounding the display region; where the peripheral region includes a target region; and the target region includes at least one of an electrode overlap region, a part of the electrode overlap region, a bonding region, a part of the bonding region, an encapsulation region, a part of the encapsulation region, or a whole of the peripheral region; residual photoresist on the base substrate and in the target region of the peripheral region; and a common layer located on the base substrate and covering at least the display region of the base substrate; where an orthographic projection of the common layer on the base substrate does not overlap with an orthographic projection of the residual photoresist on the base substrate; where the common layer is configured to transmit holes or electrons.

Optionally, in the display panel according to the embodiments of the present disclosure, a surface of the residual photoresist is connected to:

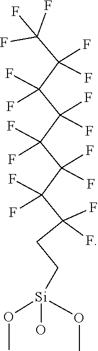 [SMILES: CO[Si](O)(CCC(F)(F)C(F)(F)C(F)(F)C(F)(F)C(F)(F)C(F)(F)C(F)(F)C(F)(F)F)OC]

Optionally, in the display panel according to the embodiments of the present disclosure, based on that the target region includes the whole of the peripheral region, the common layer covers the display region.

Optionally, in the display panel according to the embodiments of the present disclosure, based on that the target region includes at least one of the electrode overlap region, the part of the electrode overlap region, the bonding region, the part of the bonding region, the encapsulation region or the part of the encapsulation region, the common layer covers the display region and further at most covers a region in the peripheral region except the target region.

Optionally, in the display panel according to the embodiments of the present disclosure, the common layer includes at least one of a hole injection layer, a hole transport layer, an electron transport layer, or an electron injection layer.

Optionally, the display panel according to the embodiments of the present disclosure further includes: a first electrode layer disposed between the base substrate and the residual photoresist; a quantum dot light-emitting layer disposed between the hole transport layer and the electron transport layer; and a second electrode disposed on a side of the common layer facing away from the base substrate.

Correspondingly, the embodiments of the present disclosure further provide a display apparatus, including any one of the above-mentioned display panels provided in the embodiments of the present disclosure.

Correspondingly, the embodiments of the present disclosure further provide a method for manufacturing a display panel, including: providing a base substrate; where the base substrate has a display region and a peripheral region surrounding the display region; the peripheral region includes a target region; and the target region includes at least one of an electrode overlap region, a part of the electrode overlap region, a bonding region, a part of the bonding region, an encapsulation region, a part of the encapsulation region, or a whole of the peripheral region; coating a photoresist layer on an entire surface of the base substrate, exposing and developing the photoresist layer, removing at least photoresist in the display region, and retaining at least a photoresist pattern that covers the target region; coating a common layer for transmitting holes or electrons on the base substrate formed with the photoresist pattern; and removing the photoresist pattern to expose the target region, and forming the common layer in a region of the base substrate other than the target region.

Optionally, in the method according to the embodiments of the present disclosure, before coating the common layer on the base substrate, the method further includes: thinning the photoresist pattern.

Optionally, in the method according to the embodiments of the present disclosure, the thinning the photoresist pattern includes: thinning the photoresist pattern using oxygen plasma; where a surface of the thinned photoresist pattern is bonded with hydroxyl groups and carboxyl groups.

Optionally, in the method according to the embodiments of the present disclosure, after thinning the photoresist pattern using the oxygen plasma and before coating the common layer on the base substrate, the method further includes: performing lyophobic treatment on the photoresist pattern using a fluorinated silane coupling agent, so that the surface of the thinned photoresist pattern is bonded with fluorinated groups.

Optionally, in the method according to the embodiments of the present disclosure, a material of the photoresist layer includes fluororesin photoresist.

Optionally, in the method according to the embodiments of the present disclosure, the removing the photoresist pattern includes: removing the photoresist pattern using a laser stripping process.

Optionally, in the method according to the embodiments of the present disclosure, a laser power required for the laser stripping process is proportional to a size of the target region.

Optionally, in the method according to the embodiments of the present disclosure, before coating the photoresist layer on the entire surface of the base substrate, the method further includes: forming a first electrode on the base substrate. After removing the photoresist pattern to expose the target region, the method further includes: forming a second electrode on a side of the common layer facing away from the base substrate; where the second electrode overlaps with an overlapping metal in the electrode overlap region; encapsulating the base substrate formed with the second electrode; where a encapsulation material of the encapsulation region or the part of the encapsulation region contacts the base substrate; and bonding the base substrate to a peripheral circuit in the bonding region.

### BRIEF DESCRIPTION OF FIGURES

FIG. 1 is a schematic flow diagram of a method for manufacturing a display panel according to embodiments of the present disclosure.

FIG. 2 is another schematic flow diagram of a method for manufacturing a display panel according to embodiments of the present disclosure.

FIG. 3 is another schematic flow diagram of a method for manufacturing a display panel according to embodiments of the present disclosure.

FIG. 4 is another schematic flow diagram of a method for manufacturing a display panel according to embodiments of the present disclosure.

FIG. 5 is a schematic diagram of the reaction mechanism between Si—OCH₃ groups in a fluorinated silane coupling agent and —OH groups according to embodiments of the present disclosure.

FIG. 6 is another schematic flow diagram of a method for manufacturing a display panel according to embodiments of the present disclosure.

FIG. 7 is another schematic flow diagram of a method for manufacturing a display panel according to embodiments of the present disclosure.

FIG. 8A-FIG. 8L are schematic structural diagrams of a display panel after each step is performed according to embodiments of the present disclosure, respectively.

FIG. 9 is another schematic structural diagram corresponding to a manufacturing process of a display panel according to embodiments of the present disclosure.

FIG. 10 is another schematic structural diagram corresponding to a manufacturing process of a display panel according to embodiments of the present disclosure.

FIG. 11 is a schematic structural diagram of a display panel according to embodiments of the present disclosure.

FIG. 12 is a schematic structural diagram of a display apparatus according to embodiments of the present disclosure.

### DETAILED DESCRIPTION

To make objectives, technical solutions and advantages of embodiments of the present disclosure clearer, the technical solutions of the embodiments of the present disclosure will be described clearly and completely below with reference to drawings of the embodiments of the present disclosure. It is evident that the described embodiments are part of the embodiments of the present disclosure, not all of the embodiments. Moreover, the embodiments and features in the embodiments of the present disclosure may be combined with each other without conflict. Based on the described embodiments of the present disclosure, all other embodiments obtained by those skilled in the art without creative labor fall within the scope of protection of the present disclosure.

Unless otherwise defined, technical or scientific terms used in the present disclosure shall have the ordinary meanings as understood by a person of ordinary skill in the field to which the present disclosure pertains. The words such as “comprise” or “include” used in the present disclosure mean that the element or object preceding the word covers the elements or objects listed after the word and their equivalents, without excluding other elements or objects. Words such as “connect” or “couple” are not limited to physical or mechanical connections, but may include electrical connections, whether direct or indirect. Terms such as “inner”, “outer”, “upper” and “lower” are only used to indicate relative positional relationships. When the absolute position of the described object changes, the relative positional relationship may also change accordingly.

It should be noted that sizes and shapes of figures in the drawings do not reflect true proportions, and are only intended to schematically illustrate the content of the present disclosure. Moreover, the same or similar reference numerals denote the same or similar elements or elements with the same or similar functions throughout.

Currently, the production efficiency of QLEDs has not reached the mass production level, and the most important reason is that the high-resolution patterning technology for QLEDs has not yet achieved a breakthrough. The inorganic nanoparticle characteristics of quantum dots prevent them from being deposited into films and patterned through evaporation. It is difficult to achieve the high resolution when fabricating patterned quantum dots via inkjet printing.

In recent years, numerous researchers have made significant efforts in lithographically patterned quantum dots. The steps for lithographic patterning of quantum dots include film coating, exposure, and development. Layers outside the quantum dot light-emitting layer, such as a hole injection layer, a hole transport layer and an electron transport layer, are usually coated over the entire surface as a common layer. This coating method means coating both the display region and the peripheral region, resulting in the common layer covering the peripheral region. That is, regions in the peripheral region, such as an electrode overlap region (e.g., a region where the cathode is electrically connected to a cathode ring in the peripheral region), an encapsulation region (a region covered with SiNx/SiOx, Tetrafluoroethylene-based adhesive (TFE adhesive), encapsulation adhesive, etc.), and a bonding region (e.g., a region where a flexible printed circuit (FPC) is bonded to the metal pad) are all covered by the common layer. This causes the electrode overlap region and the bonding region to be non-conductive due to the coverage of the common layer. Since QLEDs are generally encapsulated with glass adhesive, covering the encapsulation region with the common layer makes effective encapsulation impossible. Therefore, selective coating of the common layer is required. In related technologies, one method for the selective coating of the common layer is to block coating nozzles corresponding to the peripheral region. This approach requires specific coating nozzles for each product design, resulting in relatively high costs.

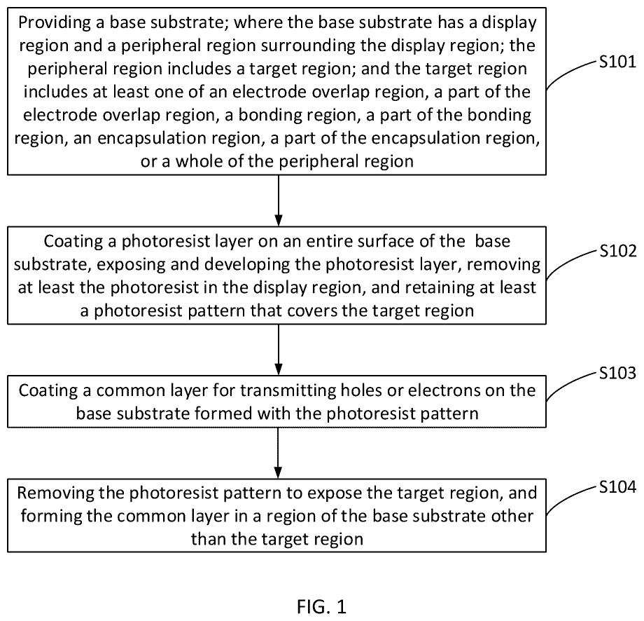

In view of the above, the embodiments of the present disclosure provide a method for manufacturing a display panel, as shown in FIG. 1, including:
S101, providing a base substrate; where the base substrate has a display region and a peripheral region surrounding the display region; the peripheral region includes a target region; and the target region includes at least one of an electrode overlap region, a part of the electrode overlap region, a bonding region, a part of the bonding region, an encapsulation region, a part of the encapsulation region, or a whole of the peripheral region;
S102, coating a photoresist layer on an entire surface of the base substrate, exposing and developing the photoresist layer, removing at least the photoresist in the display region, and retaining at least a photoresist pattern that covers the target region;
S103, coating a common layer for transmitting holes or electrons on the base substrate formed with the photoresist pattern; and
S104, removing the photoresist pattern to expose the target region, and forming the common layer in a region of the base substrate other than the target region.

In the method for manufacturing the display panel provided by the embodiments of the present disclosure, a photoresist pattern is adopted to cover at least the target region before manufacturing the common layer. Therefore, the existing coating device can be used to realize the selective coating of the common layer. After coating the common layer, the photoresist pattern is removed, so that the common layer is not formed in the target region. Since the target region includes at least one of the electrode overlap region, the part of the electrode overlap region, the bonding region, the part of the bonding region, the encapsulation region, the part of the encapsulation region or a whole of the peripheral region, this can avoid the problem that the electrode overlap region and the bonding region in the peripheral region are covered by the common layer and thus cannot conduct electricity subsequently, as well as the problem that the encapsulation region is covered by the common layer and thus effective glass adhesive encapsulation cannot be achieved.

Currently, electroluminescent devices can be classified into an upright structure and an inverted structure. The difference between the upright structure and the inverted structure lies in the different fabrication sequences of the film layers. Specifically, the upright structure is that an anode, a hole injection layer, a hole transport layer, a quantum dot light-emitting layer, an electron transport layer, and a cathode are sequentially formed on the base substrate; and the inverted structure is that an electron transport layer, a quantum dot light-emitting layer, a hole transport layer, a hole injection layer, and an anode are sequentially formed on the base substrate. The electroluminescent device in the display panel provided by the embodiments of the disclosure can be either an upright structure or an inverted structure.

It should be noted that the luminescence principle of the electroluminescent device is as follows: holes from the anode and electrons from the cathode are transported to the quantum dot light-emitting layer, where they recombine to emit light. Due to the difference in energy level barriers between the anode and the light-emitting layer, as well as between the cathode and the light-emitting layer, the transport of electrons and holes is relatively difficult, and their transport rates and quantities also differ significantly. To balance concentrations of electrons and holes, a hole injection layer and a hole transport layer are generally disposed between the quantum dot light-emitting layer and the anode, and an electron transport layer is disposed between the quantum dot light-emitting layer and the cathode. Of course, in specific implementations, the selection of required layers may vary based on practical needs.

Optionally, the common layer in the embodiments of the present disclosure may include a hole injection layer, a hole transport layer and an electron transport layer, which are not limited thereto.

Optionally, in the method for manufacturing the above display panel provided by the embodiments of the present disclosure, a material of the photoresist layer may be the positive photoresist. During exposure of the photoresist layer, a mask plate is used for shielding. The mask plate includes a light-shielding region and a light-transmitting region. The light-transmitting region corresponds to the display region, and the light-shielding region corresponds to the target region. This ensures that the display region is exposed, and the target region is shielded by the photoresist pattern.

Optionally, in the method for manufacturing the above display panel provided by the embodiments of the present disclosure, a material of the photoresist layer may be the negative photoresist. During exposure of the photoresist layer, a mask plate is used for shielding. The mask plate includes a light-shielding region and a light-transmitting region. The light-transmitting region corresponds to the target region, and the light-shielding region corresponds to the display region. This ensures that the display region is exposed, and the target region is shielded by the photoresist pattern.

In the specific implementation, in the method for manufacturing the display panel provided in the embodiments of the present disclosure, removing the photoresist pattern specifically includes: removing the photoresist pattern using a laser stripping process. Optionally, the laser stripping process includes processes such as ablating, ashing, or removing the photoresist pattern.

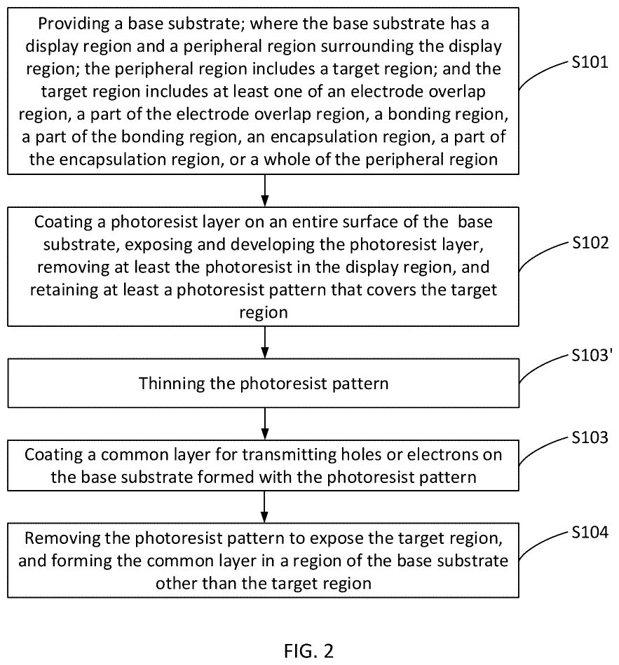

In the specific implementation, the initially coated photoresist layer is generally relatively thick, for example, 1 μm to 1.5 μm. This means the retained photoresist pattern that at least covers the target region has a thickness of 1 μm to 1.5 μm. Consequently, when using the laser stripping process to remove the photoresist pattern, a relatively high laser power is required. The excessively high laser power may cause thermal effects on the base substrate, leading to defects. Therefore, in the method for manufacturing the display panel provided in the embodiments of the present disclosure, before coating the common layer on the base substrate, as shown in FIG. 2, the method further includes:
S103′, thinning the photoresist pattern. This can reduce the laser power, mitigate the thermal effects of the laser on the base substrate, and improve product yield.

Optionally, the thickness of the thinned photoresist pattern may range from 100 nm to 500 nm, such as 100 nm, 200 nm, 300 nm, 400 nm, 500 nm, etc. The thickness of the thinned photoresist pattern is selected according to actual needs.

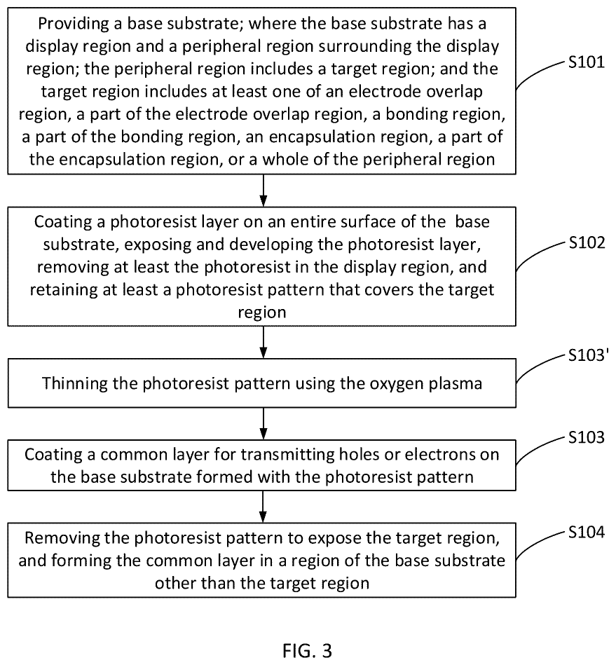

In the specific implementation, since the bottom electrode in electroluminescent device is generally made of a transparent conductive material (e.g., indium tin oxide, ITO), to prevent the method of thinning the photoresist pattern from affecting the properties of the ITO material, in the method for manufacturing the above display panel provided in the embodiments of the present disclosure, the step of thinning the photoresist pattern in S103′ of FIG. 2, as shown in FIG. 3, may specifically include:

S103′, thinning the photoresist pattern using the oxygen plasma. A surface of the thinned photoresist pattern is bonded with hydroxyl groups and carboxyl groups. This thinning method using the oxygen plasma neither affects the properties of the ITO material nor reduces the thickness of the photoresist pattern.

Optionally, the method for thinning the photoresist pattern is not limited to the method using the oxygen plasma provided in the embodiments of the disclosure, and may also include other thinning methods, as long as they do not affect the properties of the ITO material.

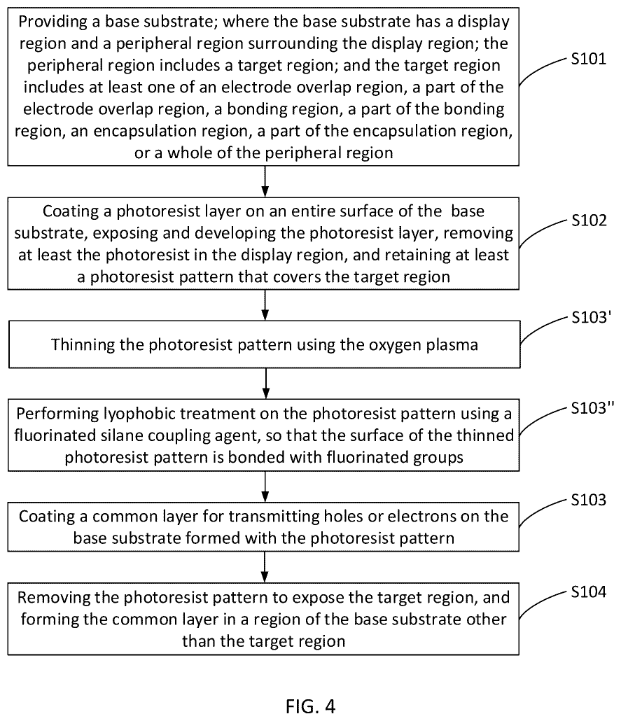

In the specific implementation, in the method for manufacturing the display panel provided in the embodiments of the present disclosure, as shown in FIG. 4, after thinning the photoresist pattern using the oxygen plasma and before coating the common layer on the base substrate, the method further includes:
S103″, performing lyophobic treatment on the photoresist pattern using a fluorinated silane coupling agent, so that the surface of the thinned photoresist pattern is bonded with fluorinated groups. Specifically, the fluorinated silane coupling agent may be

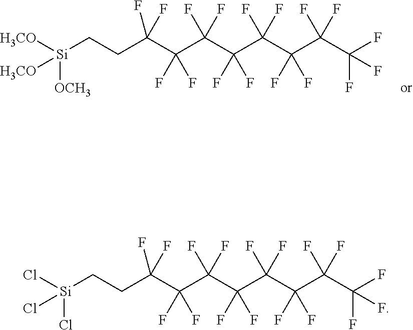 [SMILES: CO[Si](CCC(F)(F)C(F)(F)C(F)(F)C(F)(F)C(F)(F)C(F)(F)C(F)(F)C(F)(F)F)(OC)OC ; FC(F)(F)C(F)(F)C(F)(F)C(F)(F)C(F)(F)C(F)(F)C(F)(F)C(F)(F)CC[Si](Cl)(Cl)Cl]

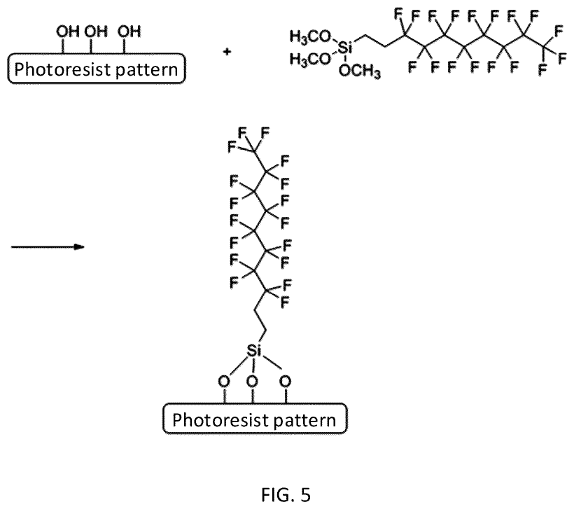

Since the surface of the thinned photoresist pattern is bonded with a large number of hydroxyl groups (—OH) and carboxyl groups (—COOH), groups in the fluorinated silane coupling agent (e.g., Si—Cl groups or Si—OCH₃ groups) react with —OH and —COOH groups, thus enabling the fluorinated chain segment and F-containing groups to form covalent bonds with the surface of the photoresist pattern. The Si—OCH₃ group in the fluorinated silane coupling agent reacts with —OH group, and its reaction mechanism is shown in FIG. 5. The fluorinated groups

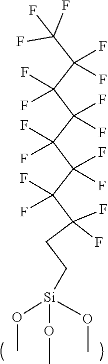

attached to the surface of the thinned photoresist pattern endow the surface of the photoresist pattern with lyophobic properties. Thus, when coating a common layer on the base substrate with the thinned photoresist pattern, the common layer cannot be coated on the surface of the thinned photoresist pattern, that is, the surface of the thinned photoresist pattern is not covered by the common layer. Therefore, when removing the photoresist pattern using the laser stripping process, only the properties of the single film layer of the photoresist pattern need to be considered, thereby reducing the difficulty of the laser stripping process.

In the specific implementation, when coating the photoresist layer, the present disclosure can use the above ordinary fluorine-free photoresist material. To reduce the laser power and the difficulty of the laser stripping process, the steps of thinning the photoresist pattern and performing lyophobic treatment on the photoresist pattern using the fluorinated silane coupling agent are required. Of course, the embodiments of the present disclosure can also directly use the fluorinated photoresist for coating the photoresist layer. Therefore, in the method for manufacturing the above display panel provided by the embodiments of the present disclosure, a material of the photoresist layer may be fluororesin photoresist. This can eliminate the steps of thinning the photoresist pattern and performing lyophobic treatment on the photoresist pattern using the fluorinated silane coupling agent, thereby reducing process complexity.

In the specific implementation, in the method for manufacturing the above display panel provided by the embodiments of the present disclosure, the target region includes at least one of an electrode overlap region, a part of the electrode overlap region, a bonding region, a part of the bonding region, an encapsulation region, a part of the encapsulation region or a whole of the peripheral region. For example, in the present disclosure, when exposing and developing the photoresist layer coated over the entire surface, the photoresist pattern covering the entire peripheral region can be retained. In this case, the formed common layer only covers the display region, thereby avoiding problems such as failure to achieve electrical connection in the electrode overlap region and the bonding region of the peripheral region, and failure to achieve effective glass encapsulation in the encapsulation region. For another example, during the exposure and development of the photoresist layer coated over the entire surface in the present disclosure, the photoresist pattern covering only the electrode overlap region, the bonding region and the encapsulation region can be retained. In this case, the formed common layer not only covers the display region but also covers a region outside the electrode overlap region, the bonding region and the encapsulation region; and the common layer located in the region outside the electrode overlap region, the bonding region and the encapsulation region neither interferes with electrode overlap and encapsulation nor affects the performance of the common layer.

In the specific implementation, in the method for manufacturing the display panel provided in the embodiments of the present disclosure, the laser power required for removing the photoresist pattern by using the laser stripping process is proportional to a size of the target region. Optionally, when the target region is the entire peripheral region, that is, the retained photoresist pattern covers the entire peripheral region during the development of the photoresist layer, when using the laser stripping process to remove the photoresist pattern, the entire photoresist pattern in the peripheral region can be removed, which requires the relatively high laser power. When the target region includes at least one of the electrode overlap region, the bonding region or the encapsulation region, that is, the retained photoresist pattern covers only at least one of the electrode overlap region, the bonding region or the encapsulation region during the development of the photoresist layer, when using the laser stripping process to remove the photoresist pattern, the entire photoresist pattern in at least one of the overlap region, the bonding region or the encapsulation region can be removed. Since the sizes of the electrode overlap region, the bonding region and the encapsulation region are smaller than that of the entire peripheral region, there is no need to use the aforementioned relatively high laser power, and the same laser stripping effect can still be achieved. When the target region includes at least one of the part of the electrode overlap region, the part of the bonding region or the part of the encapsulation region, that is, the retained photoresist pattern covers only at least one of the part of the electrode overlap region, the part of the bonding region or the part of the encapsulation region during the development of the photoresist layer, when using the laser stripping process to remove the photoresist pattern, the entire photoresist pattern in at least one of the partial overlap region, the part of the bonding region or the part of the encapsulation region can be removed. Since the sizes of the part of the electrode overlap region, the part of the bonding region and the part of the encapsulation region are smaller, a laser with the lower power can be selected to achieve the same laser stripping effect.

Optionally, for the target region with the smaller size, the laser can be further focused to remove the photoresist pattern in the target region.

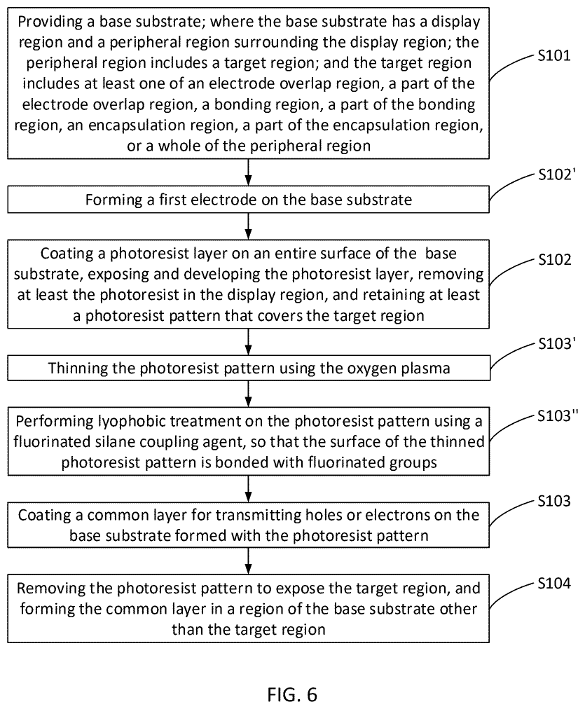

In the specific implementation, in the method for manufacturing the display panel provided in the embodiments of the disclosure, before coating the photoresist layer on the entire surface of the base substrate, as shown in FIG. 6, the method further includes: S102′, forming a first electrode on the base substrate.

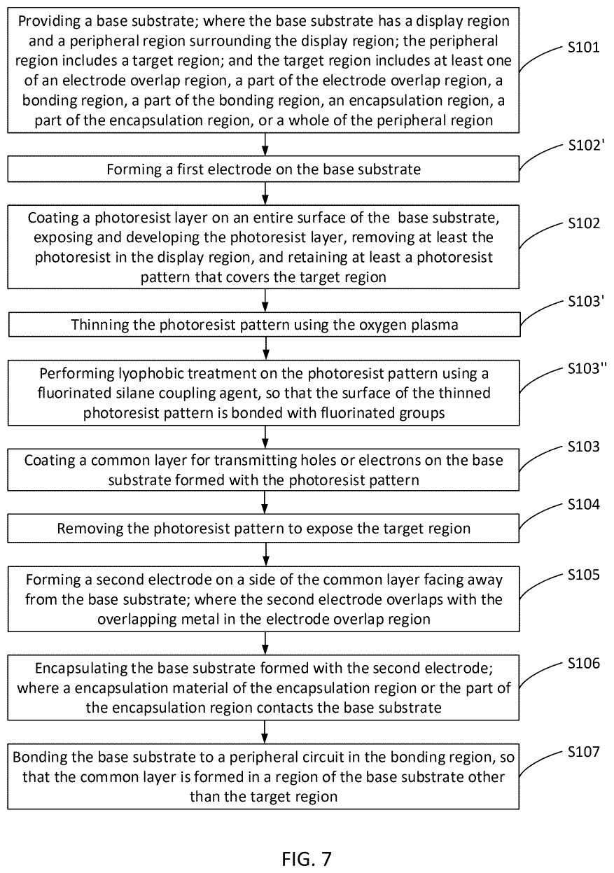

After removing the photoresist pattern to expose the target region, as shown in FIG. 7, the method further includes:
S105, forming a second electrode on a side of the common layer facing away from the base substrate; where the second electrode overlaps with the overlapping metal in the electrode overlap region;
S106, encapsulating the base substrate formed with the second electrode; where a encapsulation material of the encapsulation region or the part of the encapsulation region contacts the base substrate; and
S107, bonding the base substrate to a peripheral circuit in the bonding region.

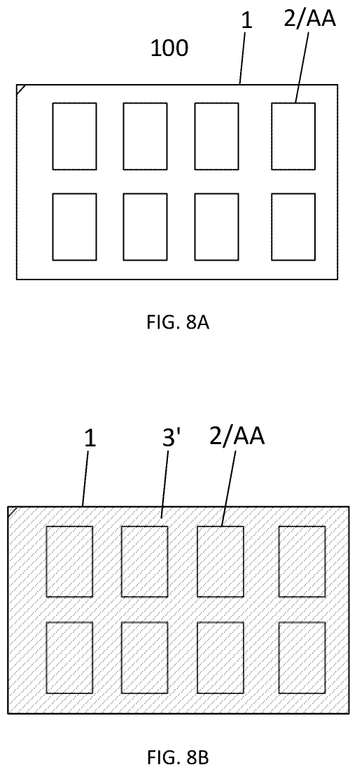

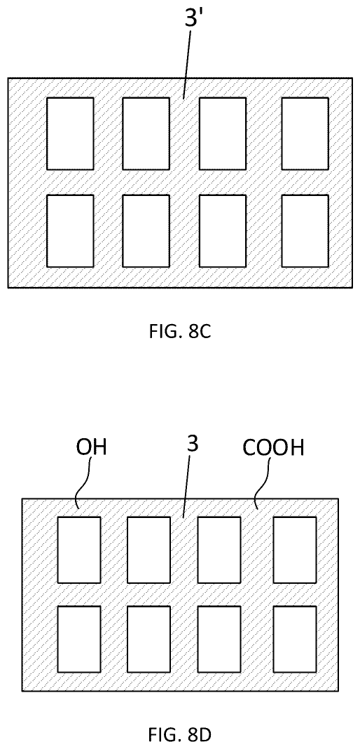

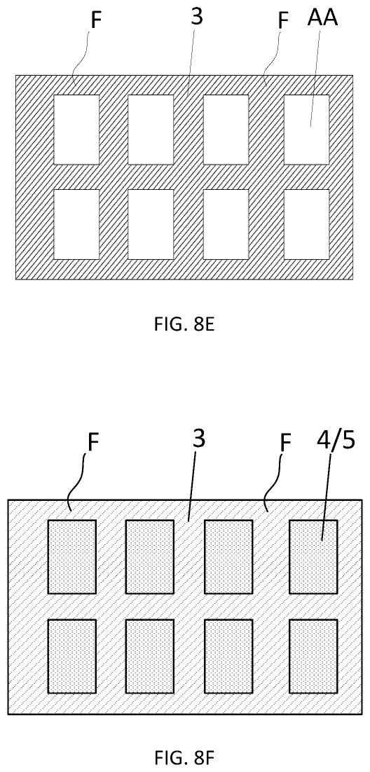

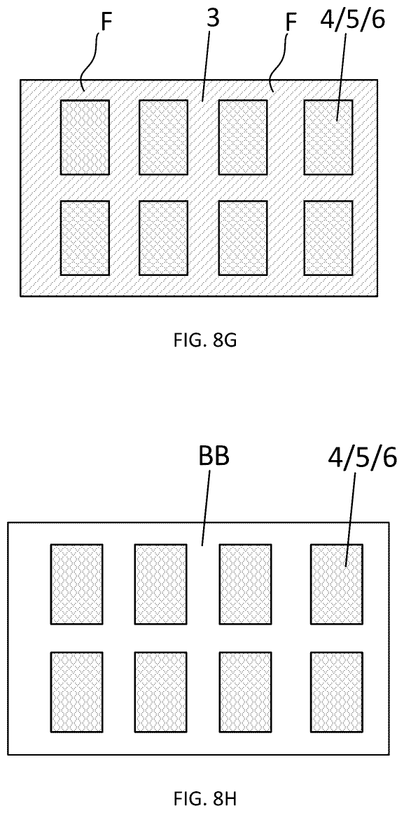

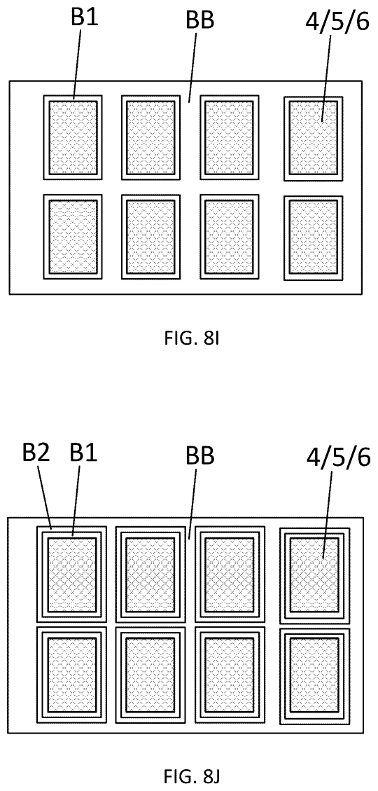

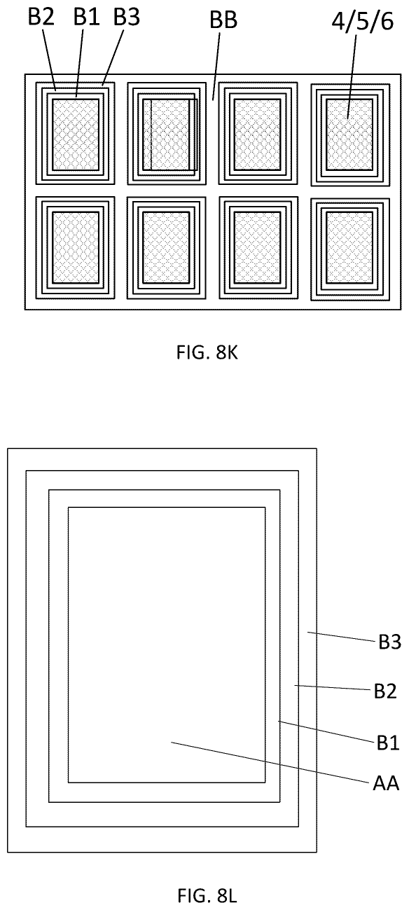

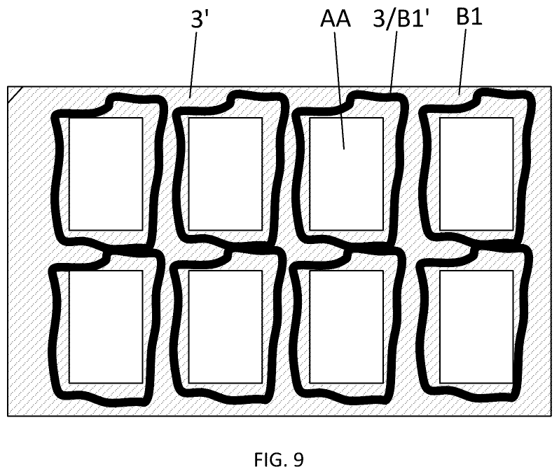

Taking a top-emitting electroluminescent device as an example, the method for manufacturing the display panel provided by the embodiments of the present disclosure is described below. When manufacturing display panels, multiple display panels (panels) are generally manufactured on a single large base substrate, and then individual display panels are obtained through cutting. The specific manufacturing process is as follows.
(1) As shown in FIG. 8A, an array mother substrate 100 is provided. The array mother substrate 100 includes a base substrate 1 and a device layer 2 arranged in a stacked manner. Herein, the device layer 2 is located in the formation region of the display region AA of each display panel. Optionally, the array mother substrate in the embodiment may be any substrate that has a base substrate and some layer structures formed on the base substrate at any stage during the manufacturing process of the display panel mother substrate. For example, the device layer 2 refers to functional film layers formed on the base substrate 1, such as a source, a gate, and a drain of a thin-film transistor.
(2) As shown in FIG. 8B, a first electrode (e.g., an anode, not shown) is formed in each display region AA of the array mother substrate 100, and a photoresist layer 3′ is coated over the entire surface on a side of the first electrode facing away from the base substrate 1.
(3) As shown in FIG. 8C, the photoresist layer 3′ is exposed and developed using a mask plate, the photoresist in the display region AA is removed, and the photoresist pattern 3 covering the target region (e.g., the entire peripheral region BB) is retained.
(4) As shown in FIG. 8D, the photoresist pattern 3 is thinned using the oxygen plasma, such that a large number of —OH and —COOH groups are attached to the surface of the thinned photoresist pattern 3.
(5) As shown in FIG. 8E, a fluorinated silane coupling agent is used to perform lyophobic treatment on the thinned photoresist pattern 3. The groups in the fluorinated silane coupling agent (e.g., Si—Cl or Si—OCH₃ groups) react with the —OH and —COOH groups, thereby forming covalent bonds between the F-containing groups

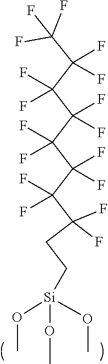

and the surface of the photoresist pattern 3. Therefore, the surface of the thinned photoresist pattern 3 is attached to fluorine-containing groups (denoted as F).
(6) As shown in FIG. 8F, a hole injection layer 4 and a hole transport layer 5 are coated on the base substrate 1 formed with the photoresist pattern 3. Since fluorine-containing groups are attached to the surface of the thinned photoresist pattern 3, the surface exhibits liquid repellency. Therefore, the hole injection layer 4 and the hole transport layer 5 basically only cover the display region AA of the display panel.
(7) A photolithographic patterning method is used to form a quantum dot light-emitting layer (not shown) located in the display region on the hole transport layer 5 shown in FIG. 8F.
(8) As shown in FIG. 8G, an electron transport layer 6 is formed on the quantum dot light-emitting layer. Since fluorine-containing groups are attached to the surface of the thinned photoresist pattern 3, the surface exhibits liquid repellency. Therefore, the electron transport layer 6 basically only covers the display region AA of the display panel. Herein, the hole injection layer 4, the hole transport layer 5, and the electron transport layer 6 constitute a common layer.
(9) As shown in FIG. 8H, the photoresist pattern 3 is removed to expose the target region (peripheral region BB), i.e., to expose the base substrate 1, such that the common layer is formed in a region of the base substrate 1 other than the target region.
(10) As shown in FIG. 8I, a second electrode (not shown) is formed on a side of the electron transport layer 6 facing away from the base substrate 1 using an evaporation process. Herein, the second electrode overlaps with the overlapping metal (not shown) in the electrode overlap region B1.
(11) As shown in FIG. 8J, the base substrate 1 formed with the second electrode is encapsulated. Herein, the encapsulation material of the encapsulation region B2 or the part of the encapsulation region (e.g., an edge of the encapsulation region) contacts the base substrate 1.
(12) As shown in FIG. 8K, the base substrate 1 is bonded and connected to the peripheral circuit (e.g., flexible printed circuit, FPC) in the bonding region B3.
(13) The base substrate 1 shown in FIG. 8K is cut to form individual display panels, as shown in FIG. 8L.

In the specific implementation, as shown in FIG. 9, for example, the target region is the part of the electrode overlap region B1′. Thus, when removing the photoresist pattern 3, only the photoresist pattern 3 in the part of the electrode overlap region B1′ needs to be removed, while the photoresist layer 3′ in the remaining regions of the electrode overlap region B1 does not need to be removed. This can reduce the laser power, and the second electrode can still overlap with the overlapping metal (not shown) in the part of the electrode overlap region B1′.

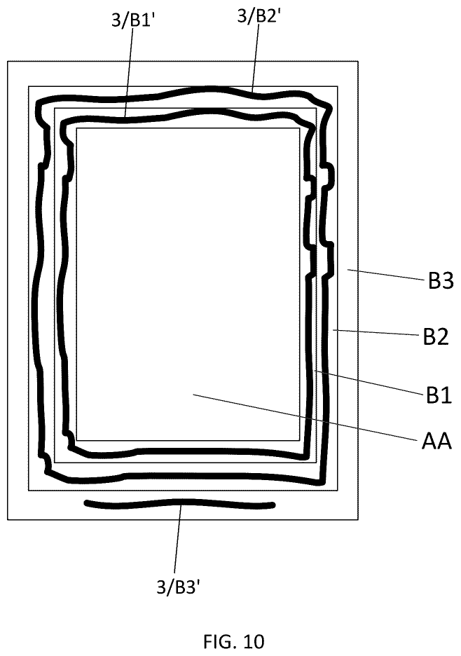

As shown in FIG. 10, for example, the target region includes the part of the electrode overlap region B1′, the part of the encapsulation region B2′, and the part of the bonding region B3′. Thus, when removing the photoresist pattern 3, only the photoresist pattern 3 in the part of the electrode overlap region B1′, the part of the encapsulation region B2′ and the part of the bonding region B3′ needs to be removed, while the photoresist layer 3′ in the remaining regions of the electrode overlap region B1, the encapsulation region B2 and the bonding region B3 does not need to be removed. This can reduce the laser power, while still enabling the second electrode to overlap with the overlapping metal (not shown) in the part of the electrode overlap region B1′, enabling the base substrate 1 to form a bonding connection with a peripheral circuit (e.g., FPC) through the part of the bonding region B3′, and enabling contact between the encapsulation material in the part of the encapsulation region B2′ and the base substrate 1 to enhance the encapsulation effect.

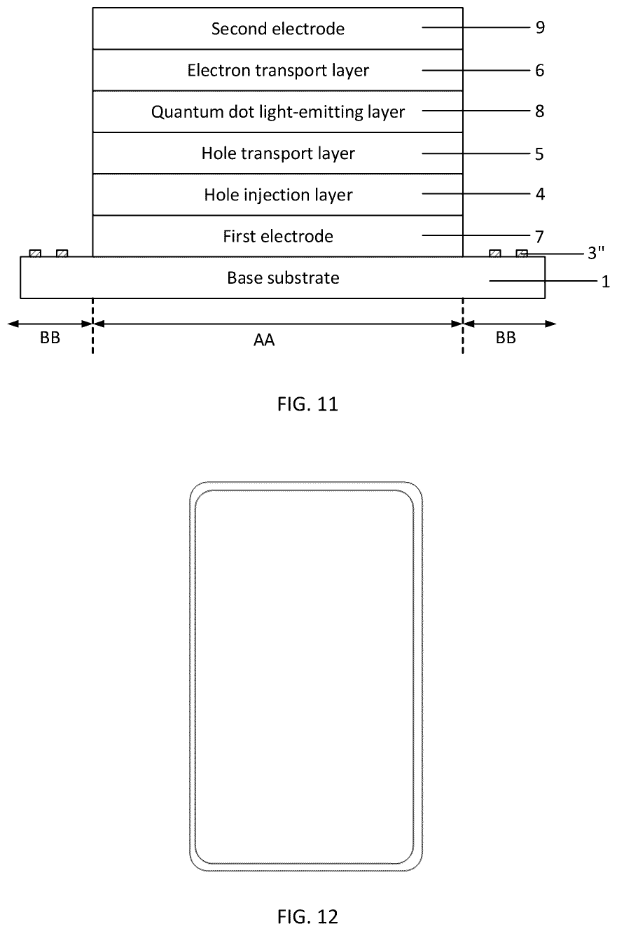

Based on the same inventive concept, the embodiments of the present disclosure further provide a display panel, as shown in FIG. 11, including:
a base substrate 1, having a display region AA and a peripheral region BB surrounding the display region AA; where the peripheral region BB includes a target region; and the target region includes at least one of an electrode overlap region B1, a part of the electrode overlap region B1′, a bonding region B3, a part of the bonding region B31, an encapsulation region B2, a part of the encapsulation region B2′, or a whole of the peripheral region BB;
residual photoresist 3″ located on the base substrate 1 and located in the target region of the peripheral region BB; and
a common layer (4, 5, and 6) located on the base substrate 1 and covering at least the display region AA of the base substrate 1. An orthographic projection of the common layer (4, 5, and 6) on the base substrate 1 does not overlap with an orthographic projection of the residual photoresist 3″ on the base substrate 1. Herein, the common layer (4, 5, and 6) is configured to transmit holes or electrons.

The display panel provided in the embodiments of the present disclosure may be fabricated using the aforementioned manufacturing method of the display panel, that is, the photoresist is used to cover the target region and expose the display region. In this way, the existing coating device can be utilized to achieve selective coating of the common layer, ensuring that the common layer does not cover the target region. Furthermore, when the laser stripping process is used to remove the photoresist pattern, due to process limitations, a small amount of residual photoresist may eventually remain in the target region. However, the small amount of residual photoresist does not affect the electrode overlapping in the peripheral region, the bonding in the bonding region, and the effective encapsulation in the encapsulation region.

In the specific implementation, for the above display panel provided by the embodiments of the present disclosure, when the display panel shown in FIG. 11 is prepared using the aforementioned method for manufacturing the display panel in the present disclosure, the surface of the residual photoresist 3″ may be bonded with fluorine-containing groups. The fluorine-containing groups may include, but are not limited to

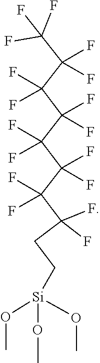 [SMILES: CO[Si](CCC(F)(F)C(F)(F)C(F)(F)C(F)(F)C(F)(F)C(F)(F)C(F)(F)C(F)(F)F)(OC)OC]

Of course, the surface of the residual photoresist 3″ may also not be bonded with fluorine-containing groups.

In the specific implementation, in the above display panel provided by the embodiments of the present disclosure, as shown in FIG. 11, the target region includes a whole of the peripheral region BB. Thus, when the display panel shown in FIG. 11 is prepared using the above method for manufacturing the display panel in the present disclosure, the common layer (4, 5, and 6) covers the display region AA.

In the specific implementation, in the above display panel provided by the embodiments of the present disclosure, the target region may include at least one of the aforementioned electrode overlap region B1, the part of the electrode overlap region B1′, the bonding region B3, the part of the bonding region B3′, the encapsulation region B2, or the part of the encapsulation region B2′ (e.g., simultaneously including B1, B2, and B3). Thus, in the display panel prepared using the aforementioned method for manufacturing the display panel in the present disclosure, the common layer (4, 5, and 6) covers the display region AA and at most covers a region in the peripheral region BB except the target region (B1, B2, and B3).

In the specific implementation, in the display panel provided by the embodiments of the present disclosure, the common layer may include at least one of a hole injection layer, a hole transport layer, an electron transport layer, or an electron injection layer. Optionally, as shown in FIG. 11, taking the upright structure of the electroluminescent device of the display panel as an example, the common layer (4, 5, and 6) may include the hole injection layer 4, the hole transport layer 5, and the electron transport layer 6.

In the specific implementation, the display panel provided in the embodiments of the present disclosure, as shown in FIG. 11, further includes: a first electrode layer 7 (anode) located between the base substrate 1 and the residual photoresist 3″; a quantum dot light-emitting layer 8 located between the hole transport layer 5 and the electron transport layer 6; and a second electrode 9 (cathode) located on a side of the common layer facing away from the base substrate 1.

The present disclosure does not restrict a light-emitting type of the electroluminescent device, for example, the light-emitting type is not limited to bottom-emitting or top-emitting.

Specifically, the display panel provided by the embodiments of the present disclosure may further include structures such as a drive circuit, a passivation layer and a planarization layer which are located between the base substrate and the first electrode.

Optionally, the base substrate may be a flexible substrate or a rigid substrate. The flexible substrate may be, for example, a polyimide (PI) substrate. The rigid substrate may be, for example, a glass substrate.

It should be noted that the embodiments of the present disclosure mainly provide a detailed description of the manufacturing method and structure of the display panel with the electroluminescent device of an upright structure. Of course, the embodiments of the present disclosure are also applicable to the manufacturing of the electroluminescent device with an inverted structure.

In the specific implementation, the display panel provided in the embodiments of the present disclosure further includes other functional film layers well-known to those skilled in the art, which will not be described in detail herein.

Based on the same inventive concept, the embodiments of the present disclosure further provide a display apparatus, which includes the above-mentioned display panel provided by the embodiments of the present disclosure. The principle of the display apparatus for solving the problem is similar to that of the aforementioned display panel; and therefore, the implementation of the display apparatus can refer to the implementation of the aforementioned display panel, and the repeated parts will not be described again herein.

In the specific implementation, the display apparatus provided in the embodiments of the present disclosure may be a full-screen display apparatus, or a flexible display apparatus, etc., which is not limited herein.

In the specific implementation, the above-mentioned display apparatus provided in the embodiments of the present disclosure may be a full-screen mobile phone as shown in FIG. 12. Of course, the above-mentioned display apparatus provided in the embodiments of the present disclosure may also be any product or component with a display function, such as a tablet computer, a television, a monitor, a laptop computer, a digital photo frame, and a navigator. Other indispensable components of the display apparatus are those that a person of ordinary skill in the art should understand as necessary. These components will not be elaborated on herein, nor shall they be considered as limitations on the present disclosure.

In the display panel and the manufacturing method therefor, and the display apparatus provided by the embodiments of the present disclosure, a photoresist pattern is adopted to cover at least the target region before manufacturing the common layer. Therefore, the existing coating device can be used to realize the selective coating of the common layer. After coating the common layer, the photoresist pattern is removed, so that the common layer is not formed in the target region. Since the target region includes at least one of the electrode overlap region, the part of the electrode overlap region, the bonding region, the part of the bonding region, the encapsulation region, the part of the encapsulation region or a whole of the peripheral region, this can avoid the problem that the electrode overlap region and the bonding region in the peripheral region are covered by the common layer and thus cannot conduct electricity subsequently, as well as the problem that the encapsulation region is covered by the common layer and thus effective glass adhesive encapsulation cannot be achieved.

Obviously, those skilled in the art can make various modifications and variations to the present disclosure without departing from the spirit and scope thereof. In this case, if such modifications and variations of the present disclosure fall within the scope of the claims of the present disclosure and their equivalent technologies, the present disclosure is also intended to include these modifications and variations.

1. A display panel, comprising:
a base substrate, having a display region and a peripheral region surrounding the display region; wherein the peripheral region comprises a target region; and the target region comprises at least one of an electrode overlap region, a part of the electrode overlap region, a bonding region, a part of the bonding region, an encapsulation region, a part of the encapsulation region, or a whole of the peripheral region;
residual photoresist on the base substrate and in the target region of the peripheral region; and
a common layer located on the base substrate and covering at least the display region of the base substrate; wherein an orthographic projection of the common layer on the base substrate does not overlap with an orthographic projection of the residual photoresist on the base substrate; wherein the common layer is configured to transmit holes or electrons.

2. The display panel according to claim 1, wherein a surface of the residual photoresist is connected to:

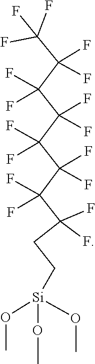 [SMILES: CO[Si](CCC(F)(F)C(F)(F)C(F)(F)C(F)(F)C(F)(F)C(F)(F)C(F)(F)C(F)(F)F)(OC)OC]

3. The display panel according to claim 1, wherein based on that the target region comprises the whole of the peripheral region, the common layer covers only the display region.

4. The display panel according to claim 1, wherein based on that the target region comprises at least one of the electrode overlap region, the part of the electrode overlap region, the bonding region, the part of the bonding region, the encapsulation region or the part of the encapsulation region, the common layer covers the display region and further at most covers a region in the peripheral region except the target region.

5. The display panel according to claim 1, wherein the common layer comprises at least one of a hole injection layer, a hole transport layer, an electron transport layer, or an electron injection layer.

6. The display panel according to claim 5, further comprising:
a first electrode disposed between the base substrate and the residual photoresist;
a quantum dot light-emitting layer disposed between the hole transport layer and the electron transport layer; and
a second electrode disposed on a side of the common layer facing away from the base substrate.

7. A display apparatus, comprising the display panel according to claim 1.

8. A method for manufacturing a display panel, comprising:
providing a base substrate; wherein the base substrate has a display region and a peripheral region surrounding the display region; the peripheral region comprises a target region; and the target region comprises at least one of an electrode overlap region, a part of the electrode overlap region, a bonding region, a part of the bonding region, an encapsulation region, a part of the encapsulation region, or a whole of the peripheral region;
coating a photoresist layer on an entire surface of the base substrate, exposing and developing the photoresist layer, removing at least photoresist in the display region, and retaining at least a photoresist pattern that covers the target region;
coating a common layer for transmitting holes or electrons on the base substrate formed with the photoresist pattern; and
removing the photoresist pattern to expose the target region, and forming the common layer in a region of the base substrate other than the target region.

9. The method according to claim 8, wherein before coating the common layer on the base substrate, the method further comprises:
thinning the photoresist pattern.

10. The method according to claim 9, wherein the thinning the photoresist pattern comprises:
thinning the photoresist pattern using oxygen plasma; wherein a surface of the thinned photoresist pattern is bonded with hydroxyl groups and carboxyl groups.

11. The method according to claim 10, wherein after thinning the photoresist pattern using the oxygen plasma and before coating the common layer on the base substrate, the method further comprises:
performing lyophobic treatment on the photoresist pattern using a fluorinated silane coupling agent, so that the surface of the thinned photoresist pattern is bonded with fluorinated groups.

12. The method according to claim 8, wherein a material of the photoresist layer comprises fluororesin photoresist.

13. The method according to claim 8, wherein the removing the photoresist pattern comprises:
removing the photoresist pattern using a laser stripping process.

14. The method according to claim 13, wherein a laser power required for the laser stripping process is proportional to a size of the target region.

15. The method according to claim 8, wherein before coating the photoresist layer on the entire surface of the base substrate, the method further comprises: forming a first electrode on the base substrate;
wherein after removing the photoresist pattern to expose the target region, the method further comprises:
forming a second electrode on a side of the common layer facing away from the base substrate; wherein the second electrode overlaps with an overlapping metal in the electrode overlap region;
encapsulating the base substrate formed with the second electrode; wherein a encapsulation material of the encapsulation region or the part of the encapsulation region contacts the base substrate; and
bonding the base substrate to a peripheral circuit in the bonding region.

16. The display apparatus according to claim 7, wherein a surface of the residual photoresist is connected to:

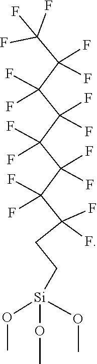 [SMILES: CO[Si](CCC(F)(F)C(F)(F)C(F)(F)C(F)(F)C(F)(F)C(F)(F)C(F)(F)C(F)(F)F)(OC)OC]

17. The display apparatus according to claim 7, wherein based on that the target region comprises the whole of the peripheral region, the common layer covers only the display region.

18. The display apparatus according to claim 7, wherein based on that the target region comprises at least one of the electrode overlap region, the part of the electrode overlap region, the bonding region, the part of the bonding region, the encapsulation region or the part of the encapsulation region, the common layer covers the display region and further at most covers a region in the peripheral region except the target region.

19. The display apparatus according to claim 7, wherein the common layer comprises at least one of a hole injection layer, a hole transport layer, an electron transport layer, or an electron injection layer.

20. The display apparatus according to claim 19, wherein the display panel further comprises:
a first electrode disposed between the base substrate and the residual photoresist;
a quantum dot light-emitting layer disposed between the hole transport layer and the electron transport layer; and
a second electrode disposed on a side of the common layer facing away from the base substrate.
